(19) United States
(12) Patent Application Publication
(10) Pub. No.: US 2024/0411302 A1
(43) Pub. Date: Dec. 12, 2024

(54) PULSE WIDTH DISPLAY SYSTEM, AND PULSE WIDTH DISPLAY METHOD

(71) Applicant: Mitsubishi Electric Corporation, Tokyo (JP)

(72) Inventor: Tomoaki YAMANE, Tokyo (JP)

(73) Assignee: Mitsubishi Electric Corporation, Tokyo (JP)

(21) Appl. No.: 18/700,854

(22) PCT Filed: Mar. 4, 2022
(86) PCT No.: PCT/JP2022/009471

§ 371 Date: Apr. 12, 2024

(51) Int. Cl. G05B 23/02; G06F 3/14

(52) U.S. Cl. CPC G05B 23/0272; G06F 3/14

(57) ABSTRACT

An input-output device includes a processor, an output circuit to output a signal to an output device, and an input circuit to receive a signal from an input device. The processor includes an output determiner and an input determiner to determine, in a failure diagnostic test, whether the output circuit or the input circuit has an abnormality based on a diagnostic pulse being a test pulse output from the output circuit to the output device or a test pulse input from the input device into the input circuit, and to transmit diagnosis result information indicating a result of the determination to a programmable logic controller, and a pulse width transmitter to detect a pulse width of the diagnostic pulse and transmit pulse width information indicating the detected pulse width to the programmable logic controller.

### TECHNICAL FIELD

The disclosure relates to an input-output device, a pulse width display system, and a pulse width display method.

### BACKGROUND ART

A programmable logic controller (PLC) is used to control a system that automates devices in a factory. The PLC transmits and receives signals to and from the devices through an input-output device to control the devices. To prevent accidents, the input-output device is to be highly reliable. The reliability may be increased by performing a failure diagnostic test during the system operation. To achieve high reliability, for example, a known input-output device may perform a dark test using a test pulse to determine whether the input-output performance is normal.

To accurately perform such a failure diagnostic test using a test pulse described above, the user may set an appropriate pulse width for the test pulse with a setting tool in a terminal connected to the PLC. However, the user cannot check the state of the test pulse and takes time to set the pulse width. Although the user may easily set the pulse width of the test pulse by uniformly setting a sufficiently large value, such an extra long pulse width may lower the response performance of the input-output device and may thus lower the performance of the entire system. An extra short pulse width being set may cause the test pulse to be susceptible to noise and may thus cause the system without failures to stop frequently.

Recent known techniques automate such pulse width setting. For example, Patent Literature 1 describes an input-output device including an auto tuner that adjusts parameters including the pulse width as appropriate for the actual environment. Patent Literature 2 describes calculating a reference noise width and setting a test width longer than the calculated reference noise width for the test pulse to avoid being susceptible to noise.

### CITATION LIST

### Patent Literature

Patent Literature 1: International Publication No. WO 2019/069433
Patent Literature 2: Japanese Patent No. 6735953

### SUMMARY OF INVENTION

### Technical Problem

The techniques described in Patent Literatures 1 and 2 allow substantially appropriate setting of the pulse width of the test pulse. However, with the techniques described in Patent Literatures 1 and 2, the user cannot check the state of the test pulse during the failure diagnostic test and may perform inappropriate pulse width setting. This may still lower the performance of the entire system or cause the system to stop frequently.

When the system stops due to an erroneous diagnosis during the failure diagnostic test, the user examines the cause and resets the pulse width. In this case, however, the user cannot check the state of the test pulse in the failure diagnostic test. The user may thus have difficulty in determining, for example, whether the erroneous diagnosis is caused by a temporary cause such as noise or by a constant cause such as faulty or aging hardware.

In response to the above circumstances, an objective of the present disclosure is to provide an input-output device, a pulse width display system, and a pulse width display method that allow a user to easily analyze a cause of an erroneous diagnosis in a failure diagnostic test.

### Solution to Problem

To achieve the above objective, an input-output device according to an aspect of the present disclosure includes a processor, an output circuit to output a signal to an output device, and an input circuit to receive a signal from an input device. The processor includes a determiner to determine, in a failure diagnostic test, whether the input circuit or the output circuit has an abnormality based on a diagnostic pulse being a test pulse output from the output circuit to the output device or a test pulse input from the input device into the input circuit, and to transmit diagnosis result information indicating a result of the determination to a controller, and a pulse width transmitter to detect a pulse width of the diagnostic pulse and transmit pulse width information indicating the detected pulse width to the controller.

### Advantageous Effects of Invention

The technique according to the above aspect of the present disclosure allows a user to easily analyze a cause of an erroneous diagnosis in a failure diagnostic test.

### BRIEF DESCRIPTION OF DRAWINGS

FIG. 1 is a block diagram of a control system incorporating an input-output device according to Embodiment 1 of the present disclosure;

FIG. 2 is a functional block diagram of a processor in the input-output device according to Embodiment 1 of the present disclosure;

FIG. 3 is diagrams illustrating example waveforms of a diagnostic pulse in Embodiment 1 of the present disclosure;

FIG. 4A is a diagram of a diagnosis result monitor screen on a display in a computer in Embodiment 1 of the present disclosure (first example);

FIG. 4B is a diagram of a diagnosis result monitor screen on the display in the computer in Embodiment 1 of the present disclosure (second example);

FIG. 4C is a diagram of a diagnosis result monitor screen on the display in the computer in Embodiment 1 of the present disclosure (third example); and

FIG. 5 is a functional block diagram of a processor in an input-output device according to Embodiment 2 of the present disclosure.

### DESCRIPTION OF EMBODIMENTS

### Embodiment 1

An input-output device 10 according to Embodiment 1 of the present disclosure is described below with reference to the drawings.

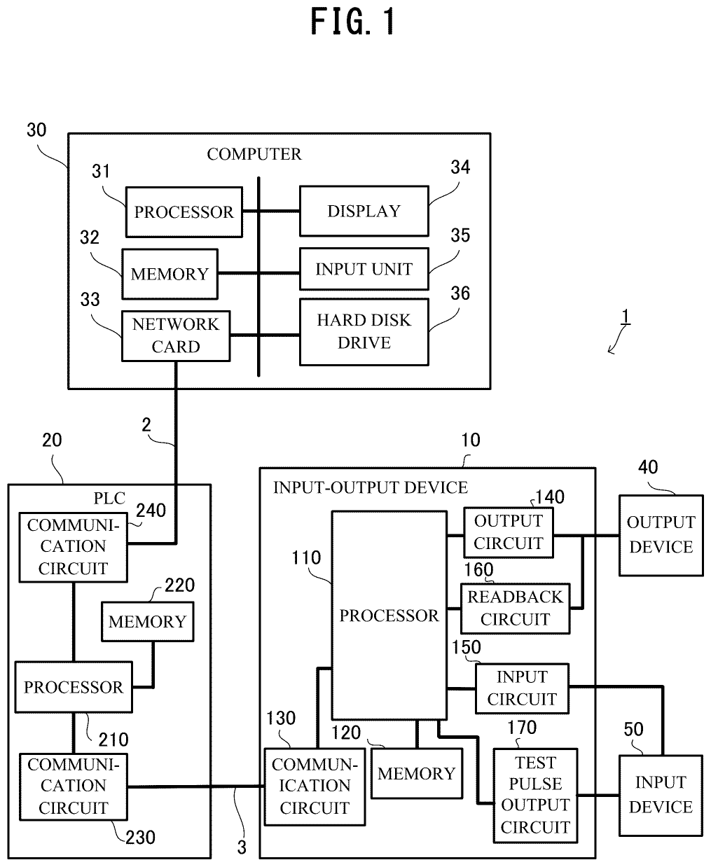

FIG. 1 is a block diagram of a control system 1 incorporating an input-output device 10 according to the present embodiment. The control system 1 controls the operations of an output device 40 and an input device 50 in a factory. The input device 50 inputs a signal into the control system 1, and may be, for example, one of various sensors or microphones. The output device 40 outputs a signal from the control system 1, and may be, for example, a display or a speaker. The control system 1 includes a computer 30 operable by a user for monitoring or providing an instruction, a programmable logic controller (PLC) 20 as a controller, and the input-output device 10 that relays a signal transmitted and received between the PLC 20 and the input device 50 or between the PLC 20 and the output device 40. The computer 30 and the PLC 20 are connected to each other with a local area network (LAN) 2 to allow communication between the computer 30 and the PLC 20. The PLC 20 and the input-output device 10 are connected to each other with a field network 3 to allow communication between the PLC 20 and the input-output device 10. The control system 1 is an example of a test pulse width display system in an aspect of the present disclosure.

Receiving a user operation, the computer 30 generates a ladder program that defines the processing details for the PLC 20 to control the input device 50 and the output device 40, and acquires and displays various items of information from the PLC 20. The computer 30 is connected to the PLC 20 to allow communication, and transmits the generated ladder program to the PLC 20.

The computer 30 is a terminal including a processor 31 that performs various processes, a memory 32 that stores various items of information, a network card 33 that transmits and receives information, a display 34 that displays information, an input unit 35 that receives operations, such as a keyboard or a mouse, and a hard disk drive 36 that stores various items of information.

The processor 31 loads an engineering tool stored in the hard disk drive 36 into the memory 32 and executes the engineering tool to preform processes such as generating a ladder program and displaying the pulse width of a diagnostic pulse described later.

The PLC 20 controls the input device 50 and the output device 40. The PLC 20 includes a processor 210 that performs various processes, a memory 220 that stores various pieces of data, a communication circuit 230 that controls communication with the input-output device 10, and a communication circuit 240 that controls communication with the computer 30.

The input-output device 10 includes a processor 110 that performs various processes, a memory 120 that stores various pieces of data, and a communication circuit 130 that controls communication with the PLC 20. The input-output device 10 also includes an output circuit 140 that outputs a signal to the output device 40 as instructed by the processor 110, and an input circuit 150 that receives a signal input from the input device 50 and transmits the signal to the processor 110. The input-output device 10 further includes a readback circuit 160 that detects a signal output from the output circuit 140 to the output device 40 and outputs the signal to the processor 110, and a test pulse output circuit 170 that transmits a test pulse to the input device 50.

The processor 110 is an arithmetic device that performs various processes. The processor 110 is connected to the memory 120, the communication circuit 130, the output circuit 140, the input circuit 150, the readback circuit 160, and the test pulse output circuit 170 to allow communication between the processor 110 and each component. The various processes performed by the processor 110 is described in detail later.

The memory 120 is a main storage that stores various pieces of data. The memory 120 serves as a work area for the processor 110 and stores various pieces of data. The memory 120 stores setting values referred to by the processor 110 in the processes described later.

The communication circuit 130 is an electronic circuit that controls communication with the PLC 20 through the field network 3.

The output circuit 140 is an electronic circuit that converts a digital signal such as a signal output from the processor 110 to control the output device 40 or a test pulse used in failure diagnostic test to an analog signal and outputs the signal to the output device 40 and the readback circuit 160.

The readback circuit 160 is an electronic circuit that converts the analog signal output from the output circuit 140 to a digital signal and outputs the signal to the processor 110.

The input circuit 150 is an electronic circuit that converts a signal input from the input device 50 to a digital signal and transmits the signal to the processor 110.

The test pulse output circuit 170 is an electronic circuit that converts the test pulse output from the processor 110 to an analog signal and outputs the signal to the input device 50.

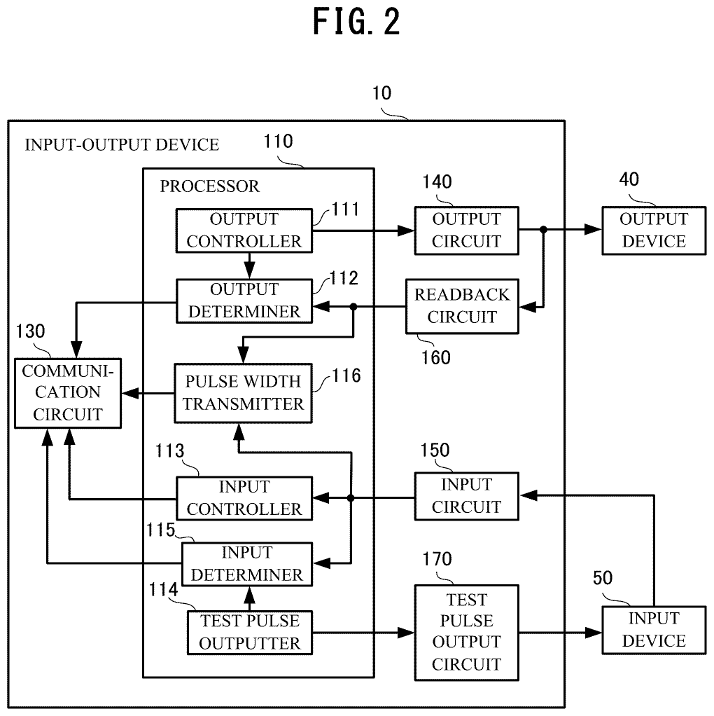

The processes performed by the processor 110 in the input-output device 10 are now described with reference to FIG. 2. The processor 110 includes, as the functional components, an output controller 111, an output determiner 112, an input controller 113, a test pulse outputter 114, an input determiner 115, and a pulse width transmitter 116.

The output controller 111 controls output of the output circuit 140. More specifically, the output controller 111 transmits various signals to the output circuit 140. The output circuit 140 converts a signal received from the output controller 111 to an analog signal and outputs the signal to the output device 40 and the readback circuit 160. The output controller 111 also transmits a test pulse to the output device 40 during an output failure diagnostic test described later. The test pulse to be transmitted is an off signal.

The output determiner 112 performs the output failure diagnostic test to determine whether the output circuit 140 has a failure. More specifically, the output determiner 112 determines, in the output failure diagnostic test, whether the output circuit 140 has a failure based on an output diagnostic pulse that is a signal resulting from a test pulse transmitted from the output controller 111 through the output circuit 140 and the readback circuit 160. The output determiner 112 also periodically transmits output diagnosis result information indicating the diagnosis result of the output failure diagnostic test to the PLC 20 through the communication circuit 130 and the field network 3. In the present embodiment, the test pulse is an off signal. The output determiner 112 compares the pulse width of the received output diagnostic pulse with the pulse width of the off signal and indicates, based on the degree of matching between the two pulse widths, the diagnosis result of the output failure diagnostic test in four levels, using good, fair, uncertain, and poor. For example, the result being good indicates that the pulse width of the received output diagnostic pulse substantially matches the pulse width of the off signal and that the output circuit 140 is operating normally, the result being poor indicates that the pulse width of the received output diagnostic pulse largely differs from the pulse width of the off signal and that the output circuit 140 is highly likely to have a failure. The process performed by the output determiner 112 is an example of determining in an aspect of the present disclosure.

The input controller 113 performs control based on the signal input from the input circuit 150. More specifically, the input controller 113 transmits the signal input from the input circuit 150 to the PLC 20 through the communication circuit 130. The PLC 20 performs processes corresponding to the received signal.

The test pulse outputter 114 transmits a test pulse to the input determiner 115 and the test pulse output circuit 170 during an input failure diagnostic test described later. The test pulse output circuit 170 transmits the test pulse received from the test pulse outputter 114 to the input device 50. The input device 50 transmits a signal corresponding to the received test pulse to the input circuit 150.

The input determiner 115 performs the input failure diagnostic test to determine whether the input circuit 150 has a failure. More specifically, the input determiner 115 determines, in the input failure diagnostic test, whether the input circuit 150 has a failure based on an input diagnostic pulse that is a signal resulting from a test pulse transmitted from the test pulse outputter 114 through the test pulse output circuit 170, the input device 50, and the input circuit 150. The input determiner 115 also periodically transmits input diagnosis result information indicating the diagnosis result of the input failure diagnostic test to the PLC 20 through the communication circuit 130 and the field network 3. In the present embodiment, the test pulse is an off signal. The input determiner 115 compares the pulse width of the received input diagnostic pulse with the pulse width of the off signal and indicates, based on the degree of matching between the two pulse widths, the diagnosis result of the input failure diagnostic test in four levels, using good, fair, uncertain, and poor. The process performed by the input determiner 115 is an example of determining in an aspect of the present disclosure.

The output failure diagnostic test performed by the output determiner 112 and the input failure diagnostic test performed by the input determiner 115 may each hereafter be referred to as a failure diagnostic test when not distinguished from each other. Similarly, the output diagnostic pulse and the input diagnostic pulse may each hereafter be referred to as a diagnostic pulse when not distinguished from each other. The output diagnosis result information and the input diagnosis result information may each hereafter be referred to as diagnosis result information when not distinguished from each other.

The pulse width transmitter 116 detects the pulse width of the diagnostic pulse during the failure diagnostic test. In other words, the pulse width transmitter 116 detects the pulse width of the output diagnostic pulse received from the readback circuit 160 during the output failure diagnostic test. The pulse width transmitter 116 also detects the pulse width of the input diagnostic pulse received from the input circuit 150 during the input failure diagnostic test. The process performed by the pulse width transmitter 116 is an example of detecting a pulse width in an aspect of the present disclosure.

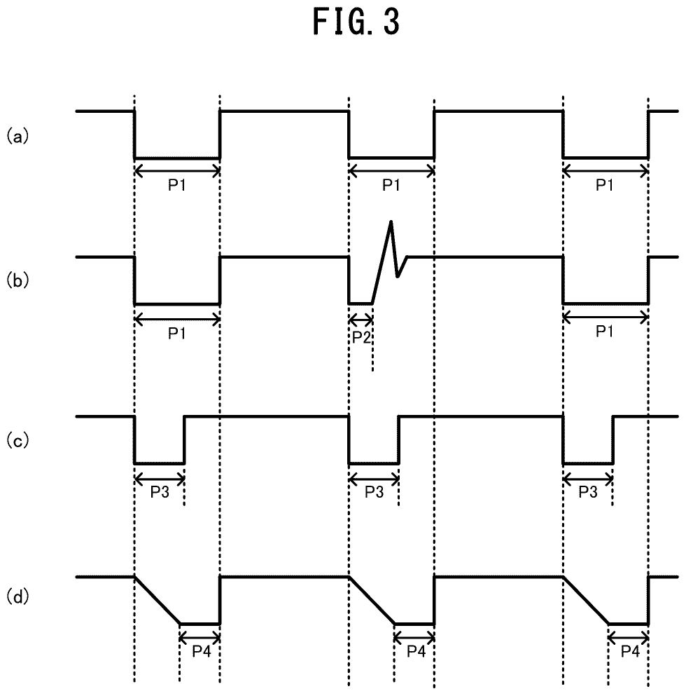

FIG. 3 illustrates example waveforms of the diagnostic pulse. FIG. 3(a) illustrates the waveform of the diagnostic pulse in a normal state. The output diagnostic pulse in a normal state indicates a waveform having a constant pulse width value P1. In this case, the pulse width transmitter 116 continuously detects the pulse width value P1.

FIG. 3(b) illustrates the waveform of the diagnostic pulse when temporary noise occurs in a normal state. The noise temporarily causes the waveform to have a pulse width value P2 shorter than the pulse width value P1 in a normal state. In this case, the pulse width transmitter 116 temporarily detects the pulse width value P2, and otherwise continuously detects the pulse width value P1.

FIG. 3(c) illustrates the waveform of the diagnostic pulse when the output circuit 140 or the input circuit 150 has a failure caused by aging. With the failure caused by aging, the waveform has a constant pulse width value P3 that is shorter than the pulse width value P1 in a normal state. In this case, the pulse width transmitter 116 continuously detects the pulse width value P3.

FIG. 3(d) illustrates the waveform of the diagnostic pulse when the output circuit 140 or the input circuit 150 has a failure caused by a capacitive load. With the failure caused by a capacitive load, the waveform has a constant pulse width value P4 that is shorter than the pulse width value of P1 in a normal state. In this case, the pulse width transmitter 116 continuously detects the pulse width value P4.

Referring back to FIG. 2, the pulse width transmitter 116 controls the communication circuit 130 to periodically transmit pulse width information indicating the detected pulse width to the PLC 20 through the communication circuit 130 and the field network 3. The pulse width information includes the date and time when the pulse width is detected.

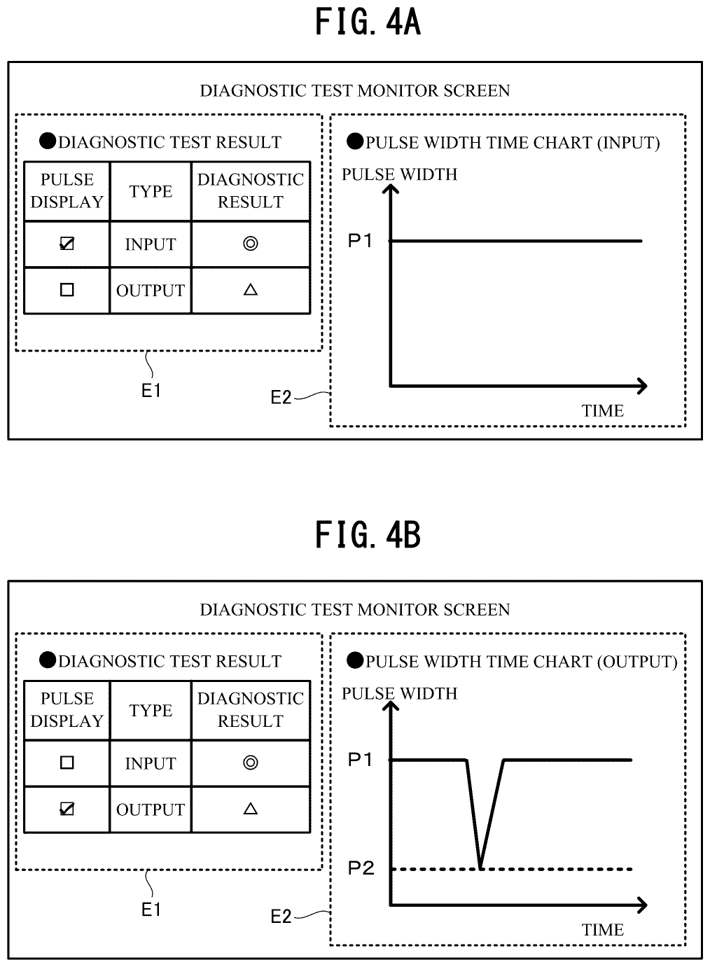

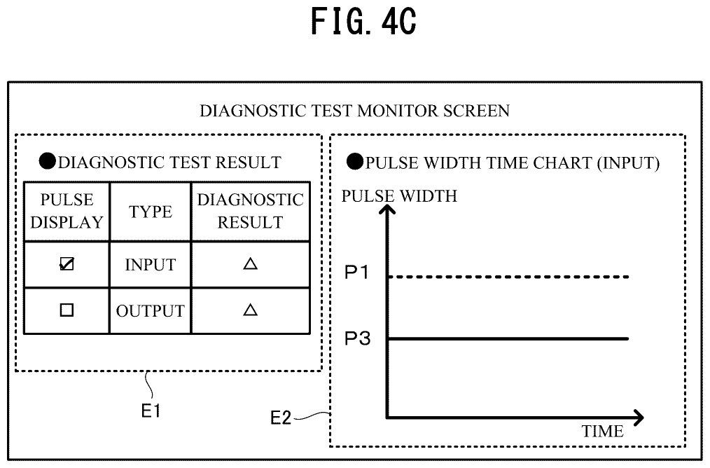

Thus, during the failure diagnostic test, the pulse width transmitter 116 in the input-output device 10 periodically transmits the pulse width information of the diagnostic pulse, and the output determiner 112 or the input determiner 115 periodically transmits the diagnosis result information of the failure diagnostic test to the PLC 20 through the communication circuit 130 and the field network 3. Each time these items of information are received from the input-output device 10, the processor 210 in the PLC 20 transfers the received items of information to the computer 30. The processor 31 in the computer 30 displays, based on the items of information received from the PLC 20, a diagnostic test monitor screen such as the screen in FIGS. 4A to 4C on the display 34. This diagnostic test monitor screen includes a diagnostic test result display area E1 that displays, in real time, the result of the latest failure diagnostic test based on the received diagnosis result information, and a pulse width display area E2 that displays, in real time, a time chart indicating the most recent change in the pulse width based on the received pulse width information. The process in which the processor 31 in the computer 30 displays the diagnostic test monitor screen on the display 34 is an example of displaying a pulse width in an aspect of the present disclosure.

The diagnostic test result display area E1 in the monitor screen displays the latest diagnosis result for each type of the failure diagnostic test in four levels, using good, fair, uncertain, and poor. The diagnostic test result display area E1 includes checkboxes for alternatively selecting the diagnostic pulse to be displayed in the pulse width display area E2. The user can specify the diagnostic pulse (the input diagnostic pulse or the output diagnostic pulse) to be displayed in the pulse width display area E2 by operating the input unit 35 in the computer to select one checkbox.

The pulse width display area E2 in the monitor screen displays the time chart indicating the most recent change in the pulse width of the diagnostic pulse corresponding to the type of the failure diagnostic test specified in the diagnostic test result display area E1. For example, the diagnostic test monitor screen illustrated in FIG. 4A includes the pulse width display area E2 that displays the latest time chart of the pulse width of the input diagnostic pulse. This time chart corresponds to the waveform of the diagnostic pulse illustrated in FIG. 3(a). The user can refer to this monitor screen and readily determine that the result of the input failure diagnostic test is good with no abnormality indicated, the input diagnostic pulse has a constant pulse width of the normal value P1, and thus the input circuit 150 is operating normally.

The diagnostic test monitor screen illustrated in FIG. 4B includes the pulse width display area E2 that displays the latest time chart of the pulse width of the output diagnostic pulse. This time chart corresponds to the waveform of the diagnostic pulse illustrated in FIG. 3(b). In this monitor screen, the result of the output failure diagnostic test is uncertain. However, although the output diagnostic pulse temporarily has the pulse width of the value P2 that is smaller than the normal value P1, the output diagnostic pulse otherwise has the pulse width of the normal value P1. The user can thus determine that the result of the output diagnostic test being uncertain is caused by the diagnostic pulse temporarily susceptible to noise, and the output circuit 140 is operating normally.

In the diagnostic test monitor screen illustrated in FIG. 4C, the pulse width display area E2 displays the latest time chart of the pulse width of the input diagnostic pulse. This time chart corresponds to the waveform of the diagnostic pulse illustrated in FIG. 3(c). In this monitor screen, the result of the input failure diagnostic test is uncertain. The pulse width of the input diagnostic pulse is constantly the value P3, which is smaller than the normal value P1. The user can thus easily determine that the input circuit 150 may have a failure.

As described above, the input-output device 10 according to the present embodiment performs the failure diagnostic test in which the pulse width of the diagnostic pulse, which is the test pulse output from the output circuit 140 to the output device 40 or the test pulse input from the input device 50 to the input circuit 150, is detected, and the pulse width information is transmitted to the PLC 20 together with the diagnosis result information indicating the result of the failure diagnostic test. The diagnosis result information and the pulse width information are then displayed in chronological order on the display 34 in the computer 30 through the PLC 20. This allows the user to easily check, together with the result of the failure diagnostic test, the actual pulse width of the test pulse transmitted through the input circuit 150 or the output circuit 140 in the failure diagnostic test. The user can thus easily determine the cause of an erroneous diagnosis in the failure diagnostic test and easily reset the pulse width after the system stops. In other words, the input-output device 10 according to the present embodiment allows the user to easily analyze the cause of an erroneous diagnosis in the failure diagnostic test.

### Embodiment 2

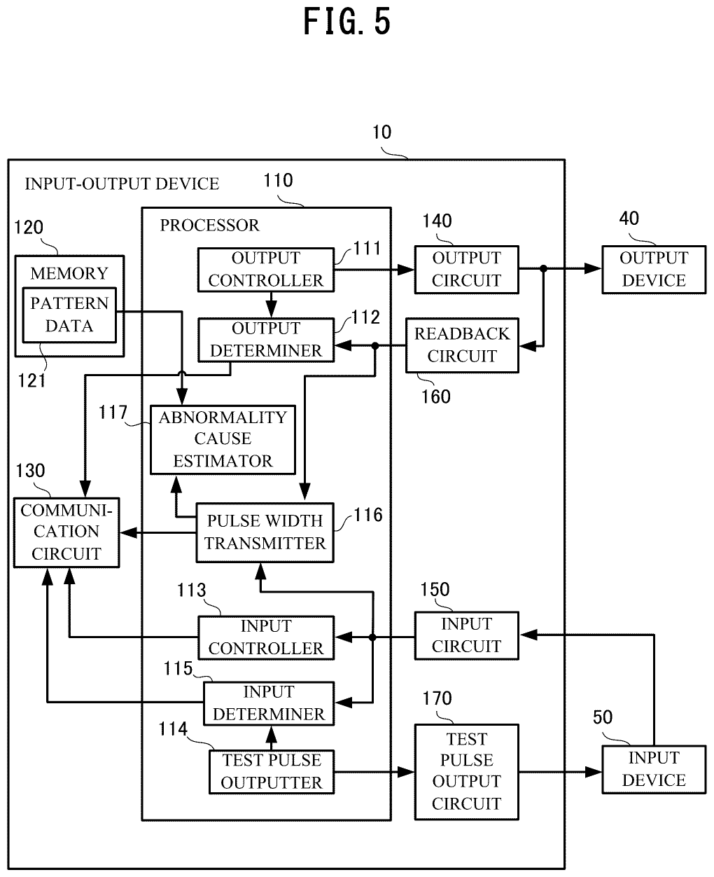

FIG. 5 is a functional block diagram of a processor 110 in an input-output device 11 according to Embodiment 2. In the present embodiment, the processor 110 includes substantially the same components as the processor 110 in the input-output device 10 according to Embodiment 1, except that the processor 110 further includes an abnormality cause estimator 117. Additionally, the memory 120 stores pattern data 121 that defines the patterns of the typical pulse width of the diagnostic pulse when an abnormality occurs and the cause of abnormality for the pulse width. The pattern data 121 may be updated with machine learning using the correspondence between an actual pulse width and the cause of abnormality for the pulse width as training data.

When the output determiner 112 or the input determiner 115 determines the presence of an abnormality (for example, the diagnosis result being poor or uncertain), the abnormality cause estimator 117 acquires the pulse width information about the diagnostic pulse from the pulse width transmitter 116, compares the information with the pattern data 121 to estimate the cause of the abnormality, and transmits the result of the estimation to the PLC 20 through the communication circuit 130 and the field network 3.

As described above, the input-output device 11 according to the present embodiment can automatically estimate the cause of abnormality instead of the user estimating the cause based on the pulse width time chart.

### Modifications

The present disclosure is not limited to the above embodiments, and may be modified variously.

For example, the pulse width transmitter 116 may average multiple sets of pulse width information and transmit average pulse width information resulting from averaging the multiple sets of pulse width information to the PLC 20. This can reduce the amount of data transmitted to the PLC 20 and thus reduce the load on the field network 3. After the averaging, temporary pulse width abnormality resulting from noise cannot be detected. The input-output device 10 may have a structure that allows the user to operate the input unit 35 in the computer 30 to determine whether such averaging is to be performed.

In the above embodiments, as illustrated in FIG. 1, both the output device 40 and the input device 50 are connected to the input-output device 10. In some embodiments, simply the output device 40 or the input device 50 may be connected to the input-output device, or multiple output devices 40 and multiple input devices 50 may be connected to the input-output device.

In the above embodiments, the test pulse is an off signal. The off signal in particular is largely susceptible to noise, and the width of the test pulse is thus to be set properly. In some embodiments, the test pulse may be an on signal.

In the above embodiments, the pulse width display area E2 in the diagnostic test monitor screen displays the time chart indicating the pulse width information about the diagnostic pulse corresponding to the type of the diagnostic test selected in the diagnostic test result display area E1. In some embodiments, the pulse width display area E2 may display a time chart of the pulse width of the input diagnostic pulse and a time chart of the pulse width of the output diagnostic pulse simultaneously. In this case, the diagnostic test result display area E1 eliminates the checkboxes for selecting the pulse to be displayed.

In the above embodiments, examples of the processor 31 in the computer 30, the processor 210 in the PLC 20, and the processor 110 in the input-output device 10 include, for example, a central processing unit (CPU), a microprocessor, and a digital signal processor (DSP). Examples of the memory 32 in the computer 30, the memory 220 in the PLC 20, and the memory 120 in the input-output device 10 include a volatile or non-volatile memory, such as a random-access memory (RAM), a read-only memory (ROM), a flash memory, an erasable programmable ROM (EPROM), and an electrically erasable programmable ROM (EEPROM).

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

### REFERENCE SIGNS LIST

1 Control system
10 Input-output circuit
110 Processor
111 Output controller
112 Output determiner
113 Input controller
114 Test pulse outputter
115 Input determiner
116 Pulse width transmitter
117 Abnormality cause estimator
120 Memory
121 Pattern data
130 Communication circuit
140 Output circuit
150 Input circuit
160 Readback circuit
170 Test pulse output circuit
20 PLC
210 Processor
220 Memory
230, 240 Communication circuit
30 Computer
31 Processor
32 Memory
33 Network card
34 Display
35 Input unit
36 Hard disk drive
40 Output device
50 Input device

1. A pulse width display system, comprising:
an input-output device including
a processor,
an output circuit to output a signal to an output device, and
an input circuit to receive a signal from an input device;
a controller; and
a terminal, wherein
the processor of the input-output device includes
an output determiner to perform an output failure diagnostic test to determine whether the output circuit has a failure based on an output diagnostic pulse being a test pulse output from the output circuit to the output device, and transmit output diagnosis result information indicating a result of the determination to the controller,
an input determiner to perform an input failure diagnostic test to determine whether the input circuit has a failure based on an input diagnostic pulse being a test pulse input from the input device into the input circuit, and transmit input diagnosis result information indicating a result of the determination to the controller, and
a pulse width transmitter to detect a pulse width of the input diagnostic pulse or the output diagnostic pulse and transmit pulse width information indicating the detected pulse width to the controller,
the controller transmits, to the terminal, the output diagnosis result information, the input diagnosis result information, and the pulse width information received from the processor, and
the terminal
receives selection of a type of the test pulse, and
displays a diagnosis result from the determination by the input determiner, a diagnosis result from the determination by the output determiner, and a time chart indicating a most recent change in the pulse width of the output diagnostic pulse or the input diagnostic pulse corresponding to the received type during the determination in association with each other, based on the output diagnostic result information, the input diagnosis result information, and the pulse width information received from the controller.

2. The pulse width display system according to claim 1, wherein
the input-output device includes an abnormality cause estimator to estimate, upon the output determiner or the input determiner determining a presence of an abnormality, a cause of the abnormality based on pattern data about a pulse width of the output diagnostic pulse or the input diagnostic pulse when the abnormality occurs.

3. The pulse width display system according to claim 2, wherein
the pattern data is updated with machine learning.

4. The pulse width display system according to claim 1, wherein
the pulse width transmitter averages a plurality of sets of the pulse width information and transmits average pulse width information resulting from the averaging to the controller, and
the pulse width transmitter receives a user instruction as to whether to average the plurality of sets of pulse width information.

5. (canceled)

6. A pulse width display method, comprising:
determining whether an input circuit or an output circuit has an abnormality based on a diagnostic pulse being a test pulse output from the output circuit to an output device or a test pulse input from an input device into the input circuit;
detecting a pulse width of the diagnostic pulse;
receiving selection of a type of the test pulse; and
displaying a diagnosis result from the determination in the determining and a time chart indicating a most recent change in the pulse width of the diagnostic pulse during the determination detected by the detecting in association with each other, the diagnostic pulse corresponding to the type received by the receiving.
